(19) United States
(12) Patent Application Publication
(10) Pub. No.: US 2026/0068433 A1
(43) Pub. Date: Mar. 5, 2026

(54) DISPLAY DEVICE AND MANUFACTURING METHOD OF DISPLAY DEVICE

(71) Applicant: Samsung Display Co., Ltd., Yongin-Si (KR)

(72) Inventors: Ji-Hwan KIM, Yongin-si (KR); JONGHOON CHOI, Yongin-si (KR)

(21) Appl. No.: 19/079,455

(22) Filed: Mar. 14, 2025

(30) Foreign Application Priority Data
Jul. 2, 2024 (KR) 10-2024-0087018
Sep. 23, 2024 (KR) 10-2024-0128190

(51) Int. Cl. H10K 59/121; H10D 86/40; H10K 59/12

(52) U.S. Cl. CPC H10K 59/1213; H10D 86/421; H10K 59/1201

(57) ABSTRACT

The present disclosure provides a display device including: a substrate having edges that extend in a first direction and a second direction; a transistor disposed on the substrate; and a light emitting element electrically connected to the transistor, wherein the transistor includes a semiconductor layer including single-crystal silicon, the semiconductor layer includes a plurality of protrusions, a distance between the protrusions is 1.5 μm or less, and the protrusions are oblique to at least one of the first direction and the second direction in a plan view.

### CROSS-REFERENCE TO RELATED APPLICATIONS

This application claims priority to and the benefit of Korean Patent Application No. 10-2024-0087018 filed at the Korean Intellectual Property Office on Jul. 2, 2024, and Korean Patent Application No. 10-2024-0128190 filed at the Korean Intellectual Property Office on Sep. 23, 2024, the entire contents of which are incorporated herein by reference.

### BACKGROUND

### (a) Technical Field

The present disclosure relates to a display device and a manufacturing method of the display device, and more specifically to a display device capable of improving electron mobility and ameliorating a current leak problem, and a method of manufacturing the same.

### (b) Description of the Related Art

A display device has a pixel circuit for each pixel, and the pixel circuit may include a transistor. The transistor may include at least one of amorphous silicon, polycrystalline silicon, and single-crystal silicon. The closer it is to single-crystal silicon, the higher the electron mobility. Transistors with higher electron mobility have better performance, enabling implementation of high-resolution display devices.

### SUMMARY

Embodiments are intended to provide a display device and a manufacturing method therefor capable of improving electron mobility and ameliorating a current leak problem.

An embodiment of the present disclosure provides a display device including: a substrate having edges that extend in a first direction and a second direction; a transistor disposed on the substrate; and a light emitting electrically connected to the transistor, wherein the transistor includes a semiconductor layer including single-crystal silicon, the semiconductor layer includes a plurality of protrusions, a distance between the plurality of protrusions is 1.5 μm or less, and each of the plurality of protrusions extends in a line that is oblique to at least one of the first direction and the second direction in a plan view.

The distance between the plurality of protrusions may be 0.9 μm or less.

The distance between the plurality of protrusions may be 0.878 μm or less.

The plurality of protrusions may form an angle of 30° to 60° with respect to at least one of the first direction and the second direction.

The plurality of protrusions may extend in a direction perpendicular to a <100> silicon crystal direction in a plan view.

A height of the plurality of protrusions in a cross-sectional view may be 6 nm or less.

The height of the plurality of protrusions in a cross-sectional view may be 4 nm or less.

The transistor may further include a source electrode and a drain electrode electrically connected to the semiconductor layer; and a gate electrode overlapping a portion of the semiconductor layer. The light emitting element may be electrically connected to at least one of the source electrode or the drain electrode.

An embodiment of the present disclosure provides a manufacturing method for a display device, including: preparing a substrate having edges that extend in a first direction and a second direction; forming a transistor on a substrate; and forming a light emitting element electrically connected to the transistor, wherein the forming of the transistor includes: forming an amorphous silicon layer; attaching a single-crystal silicon chip to a corner of the amorphous silicon layer; and forming a single-crystal silicon layer by moving a laser beam from the corner of the amorphous silicon layer toward another corner, wherein a moving direction of the laser beam is oblique to at least one of the first direction and the second direction in a plan view.

A beam width of the laser beam may be 3 μm or less.

A scan pitch of the laser beam may be less than or equal to ½ of the beam width.

The scan pitch of the laser beam may be 0.878 μm or less.

The moving direction of the laser beam may be 30° to 60° relative to one of the first direction and the second direction.

The forming of the transistor may include: forming a single-crystal silicon pattern by etching the single-crystal silicon layer; forming a gate electrode on the single-crystal silicon pattern; and forming a semiconductor layer by partially implanting ions into the single-crystal silicon pattern.

An embodiment of the present disclosure provides a manufacturing method for a display device, including: preparing a substrate having edges that extend in a first direction and a second direction; forming a transistor on a substrate; and forming a light emitting element electrically connected to the transistor, wherein the forming of the transistor includes: forming an amorphous silicon layer; forming a first area and a second area connected to a corner of the first area by etching the amorphous silicon layer, the second area having a width of 0.3 μm or less; and forming a single-crystal silicon layer by moving a laser beam from the second area to another corner of the first area, and a moving direction of the laser beam is oblique to at least one of the first direction and the second direction in a plan view.

A beam width of the laser beam may be 3 μm or less.

A scan pitch of the laser beam may be less than or equal to ½ of the beam width.

The scan pitch of the laser beam may be 0.878 μm or less.

The moving direction of the laser beam may be 30° to 60° relative to at least one of the first direction and the second direction.

The second area irradiated by the laser beam may be made of single-crystal silicon.

A display device according to an embodiment may have improved electron mobility, thereby reducing power consumption and current leakage.

### BRIEF DESCRIPTION OF THE DRAWINGS

FIG. 1 is a schematic perspective view showing a use state of a display device according to an embodiment.

FIG. 2 is an exploded perspective view of a display device according to an embodiment.

FIG. 3 is a cross-sectional view showing a portion of a display area in a display device according to an embodiment.

FIG. 4 is an enlarged cross-sectional view of a region A of FIG. 3.

FIG. 5 is a top plan view schematically showing a plurality of protrusions in a semiconductor layer.

FIG. 6 to FIG. 16 illustrate a manufacturing method for a display device according to an embodiment.

FIG. 17 is a top plan view showing a manufacturing method for a display device according to an embodiment.

### DETAILED DESCRIPTION

The present disclosure will be described more fully hereinafter with reference to the accompanying drawings, in which embodiments of the disclosure are shown. As those skilled in the art would realize, the described embodiments may be modified in various ways without departing from the spirit or scope of the present disclosure.

To clearly describe the present disclosure, parts that are irrelevant to the description are omitted, and like numerals refer to like or similar components throughout the specification.

Further, since sizes and thicknesses of constituent members shown in the accompanying drawings are arbitrarily given for better understanding and ease of description, the present disclosure is not limited to the illustrated sizes and thicknesses. In the drawings, the thicknesses of layers, films, panels, regions, etc., may be exaggerated for clarity. In the drawings, for better understanding and ease of description, the thicknesses of some layers and areas are exaggerated.

It should be understood that when an element such as a layer, film, region, area or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the word “comprise” and variations such as “comprises” and “comprising” should be understood to imply the inclusion of stated elements but not the exclusion of any other elements.

Further, throughout the specification, the phrase “in a plan view” means when an object portion is viewed from above, and the phrase “in a cross-sectional view” means when a cross-section taken by vertically cutting an object portion is viewed from the side.

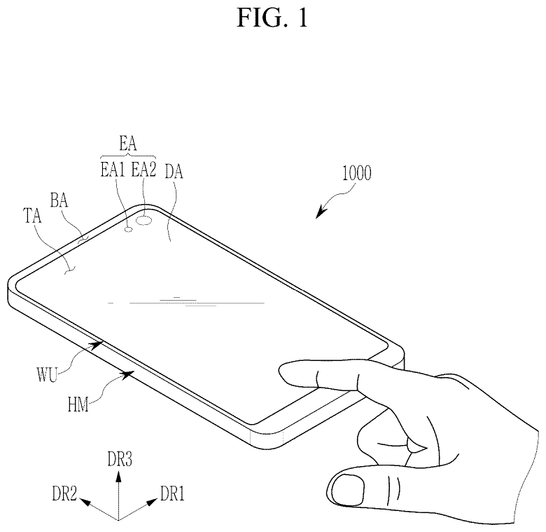

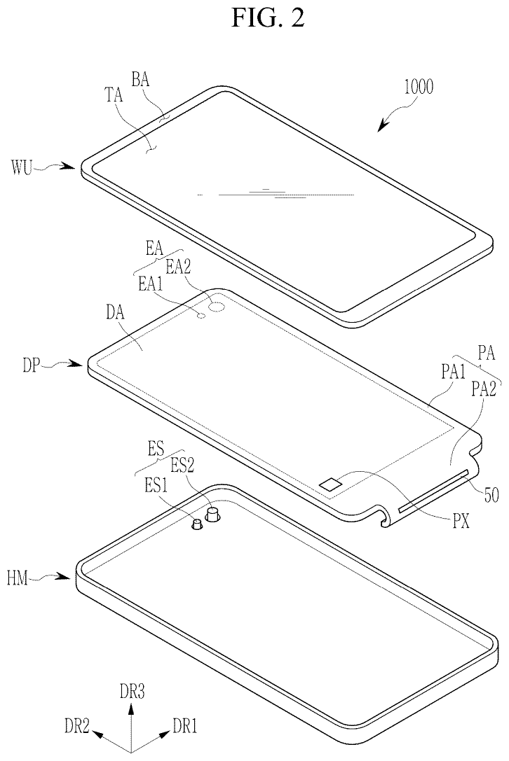

Hereinafter, a schematic structure of a display device will be described with reference to FIG. 1. FIG. 1 is a schematic perspective view showing a state of use of a display device according to an embodiment. FIG. 2 is an exploded perspective view of a display device according to an embodiment.

Referring to FIG. 1, the display device 1000 according to an embodiment, which is a device for displaying a moving image or a still image, may be used as a display screen of various electronic devices, such as a television, a laptop computer, a monitor, a billboard, the Internet of things (IOT), etc., as well as portable electronic devices such as a mobile phone, a smart phone, a tablet personal computer, a mobile communication terminal, an electronic notebook, an e-book, a portable multimedia player (PMP), a navigation system, and an ultra-mobile PC (UMPC). In addition, the display device 1000 according to an embodiment may be used in a wearable device such as a smart watch, a watch phone, a glasses display, or a head mounted display (HMD). In addition, the display device 1000 according to an embodiment may be used as an instrument panel of a vehicle, a center information display (CID) provided at a center fascia or dashboard of a vehicle, a room mirror display that replaces a side mirror of a vehicle, or a display provided on a back surface of a front seat of a vehicle. FIG. 1 is the display device 1000 being used as a smart phone for convenience of description.

The display device 1000 may display an image in a third direction DR3 on a display surface parallel to each of a first direction DR1 and a second direction DR2. A display surface on which an image is displayed may correspond to a front surface of the display device 1000, and may correspond to a front surface of a cover window WU. The image may include a still image as well as a dynamic image.

In the present embodiment, a front surface (or upper surface) and a rear surface (or lower surface) of each member are defined based on a direction in which the image is displayed. The front and rear surfaces may be opposite to each other and separated in the third direction DR3. A direction that is orthogonal to each of the front and rear surfaces may be parallel to the third direction DR3. A distance between the front surface and the rear surface in the third direction DR3 may correspond to a thickness of the display panel in the third direction DR3.

The display device 1000 according to an embodiment may sense a user input (refer to a hand in FIG. 1) applied from the outside. The user input may include various types of external inputs, such as the detection of a part of a user's body, light, heat, or pressure. In an embodiment, the user input is illustrated as a user hand applied to the front surface. However, the present disclosure is not limited thereto.

Referring to FIG. 1 and FIG. 2, the display device 1000 may include a cover window WU, a housing HM, and a display panel DP. In an embodiment, the cover window WU and the housing HM may be combined to form the display device 1000.

The cover window WU may include an insulating panel. For example, the cover window WU may be formed of glass, plastic, or a combination thereof.

A front surface of the cover window WU may act as the front surface of the display device 1000. A transmissive area TA may be an optically transparent area. For example, the transmissive area TA may be an area having visible ray transmittance of about 90% or more.

A blocking area BA defines a shape of the transmissive area TA. The blocking area BA may be adjacent to the transmissive area TA, to surround the transmissive area TA. The blocking area BA may be an area having relatively low light transmittance compared to the transmissive area TA.

The display panel DP may include a pixel PX that displays an image and a driver 50, and the pixel PX is disposed in a display area DA and a component area EA. The display panel DP may include a front surface including a display area DA and a non-display area PA. In an embodiment, the display area DA and the component area EA are an area in which an image is displayed by including pixels, and may be areas where a touch sensor is disposed above the pixel in the third direction DR3 to sense an external input.

A transmissive area TA of the cover window WU may at least partially overlap the display area DA and the component area EA of the display panel DP. For example, the transmissive area TA may overlap an entire surface of the display area DA and the component area EA, or may at least partially overlap the display area DA and the component area EA.

The non-display area PA of the display panel DP may at least partially overlap the blocking area BA of the cover window WU. The non-display area PA may be an area covered by a blocking area BA. The non-display area PA may be adjacent to the display area DA, and may surround the display area DA. The non-display area PA may include a first peripheral area PA1 in which the display area DA is disposed outside, and a second peripheral area PA2 including the driver 50, a connection wire, and a bending area.

In an embodiment, the display panel DP may be assembled in a flat state in which the display area DA, the non-display area PA, and the component area EA face the cover window WU. However, the present disclosure is not limited thereto. A portion of the non-display area PA of the display panel DP may be bent.

In addition, the display panel DP may include the component area EA, and specifically, a first component area EA1 and a second component area EA2. The first component area EA1 and the second component area EA2 may be at least partially surrounded by the display area DA. The first component area EA1 and the second component area EA2 may be areas in which an optical element ES that uses infrared rays, visible light, or sound is disposed.

The display area DA and the component area EA are formed with a plurality of light emitting diodes and a plurality of pixel circuit units that generate and transmit a light emitting current to each of the light emitting diodes. Herein, one light emitting diode and one pixel circuit unit is referred to as a pixel PX. One pixel circuit unit and one light emitting diode may be formed in a one-to-one manner in the display area DA and the component area EA.

The second peripheral area PA2 may include a bending portion. The display area DA and the first peripheral area PA1 may have a flat state that is substantially parallel to a plane defined by the first direction DR1 and the second direction DR2, and a first side of the second peripheral area PA2 may include a bending portion. As a result, at least a portion of the second peripheral area PA2 may be bent and assembled to be disposed on a back side of the display area DA.

The driver 50 may be mounted on the second peripheral area PA2, and may be mounted on the bending portion or disposed on either side of the bending portion. The driver 50 may be provided in the form of a chip.

The driver 50 may be electrically connected to the display area DA and the component area EA to transmit electrical signals to pixels in the display area DA and the component area EA. For example, the driver 50 may provide data signals to the pixels PX disposed in the display area DA. Alternatively, the driver 50 may include a touch driving circuit, and may be electrically connected to a touch sensor TS disposed in the display area DA and the component area EA.

Meanwhile, the display device 1000 may include a pad portion disposed at an end of the second peripheral area PA2, and may be electrically connected to a flexible printed circuit board (FPCB) including a driving chip by means of a pad portion. Herein, the driving chip disposed on the flexible printed circuit board may include various driving circuits for driving the display device 1000, connectors for supplying power, etc.

The optical element ES may be disposed at a lower portion of the display panel DP. The optical element ES may include a first optical element ES1 overlapping the first component area EA1 and a second optical element ES2 overlapping the second component area EA2. The first optical element ES1 may use infrared rays, and in this case, a layer that does not transmit light, such as a light blocking member, may overlap the first component area EA1.

The first optical element ES1 may be an electronic element using light or sound. The second optical element ES2 may be at least one of a camera, an infrared camera, a dot projector, an infrared illuminator, or a time-of-flight sensor.

The housing HM may be coupled to the cover window WU. The housing HM may be coupled to the cover window WU to provide a predetermined accommodation space. The housing HM may be coupled to the cover window WU to provide a predetermined accommodation space. The display panel DP and the optical element ES may be accommodated in the predetermined accommodation space provided between the housing HM and the cover window WU.

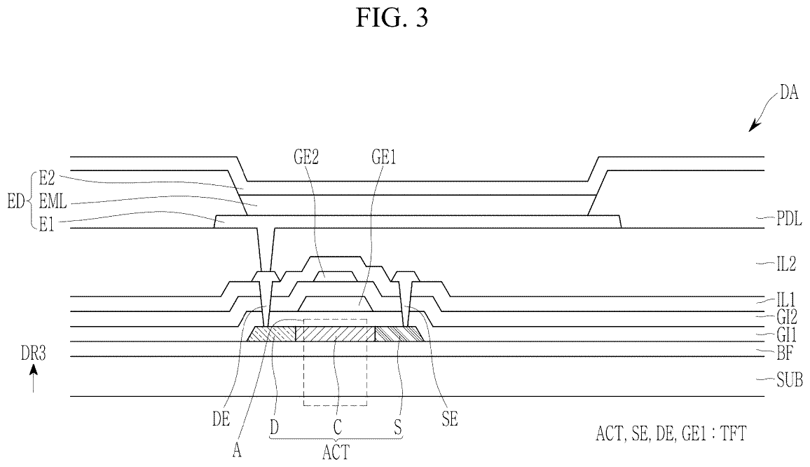

Hereinafter, a display device according to an embodiment will be described with reference to FIG. 3, centering on a cross-sectional view in the display area. FIG. 3 is a cross-sectional view showing a portion of a display area in a display device according to an embodiment.

Referring to FIG. 3, a substrate SUB may include a material having a rigid characteristic such as glass, or a flexible material that is bendable, such as plastic or polyimide. The substrate SUB may extend in the first direction DR1 and the second direction DR2.

A buffer layer BF may be disposed on the substrate SUB. The buffer layer BF may planarize a surface of the substrate SUB and block penetration of impure elements. The buffer layer BF may include an inorganic material, and for example, may include an inorganic insulating material such as silicon nitride (SiNₓ), silicon oxide (SiOₓ), and silicon oxynitride (SiOₓN_{y}).

A semiconductor layer ACT may be disposed on the buffer layer BF. The semiconductor layer ACT of the display device according to an embodiment may include single-crystal silicon. Furthermore, the semiconductor layer ACT may include polycrystalline silicon having a crystal size of several micrometers or more. Accordingly, any undesirable effect of grain boundaries may be reduced and electron mobility may be improved, reducing power consumption. Furthermore, current leakage problems due to defects may be improved. Furthermore, a difference in grain characteristics depending on the direction may be reduced, so improving the device characteristics in all directions.

The semiconductor layer ACT may include a channel region C, a source region S, and a drain region D that are distinguished depending on whether or not they are doped with impurities. The source region S and the drain region D may have conductive characteristics corresponding to a conductor.

A first gate insulating layer GI1 may be disposed on the semiconductor layer ACT. The first gate insulating layer GI1 may cover the semiconductor layer ACT and the substrate SUB. The first gate insulating layer GI1 may include an inorganic insulating material such as silicon nitride (SiNₓ), silicon oxide (SiOₓ), and silicon oxynitride (SiOₓN_{y}). The first gate insulating layer GI1 may have a single-layer or multi-layer structure including the above inorganic insulating material.

A gate electrode GE1 may be disposed on the first gate insulating layer GI1. The gate electrode GE1 may include a metal such as copper (Cu), molybdenum (Mo), aluminum (Al), silver (Ag), chromium (Cr), or tantalum (Ta), or a metal alloy thereof. The gate electrode GE1 may be formed as a single layer or a multilayer. A region overlapping the gate electrode GE1 in the semiconductor layers ACT in a plan view may be the channel region C.

A second gate insulating layer GI2 may be disposed on the gate electrode GE1. The second gate insulating layer GI2 may include an inorganic insulating material such as silicon nitride (SiNₓ), silicon oxide (SiOₓ), and silicon oxynitride (SiOₓN_{y}). The second gate insulating layer GI2 may have a single-layer or multi-layer structure including the above inorganic insulating material.

A capacitor electrode GE2 may be disposed on the second gate insulating layer GI2. The capacitor electrode GE2 may overlap the gate electrode GE1 to form a capacitor.

A first insulating layer IL1 may be disposed on the capacitor electrode GE2. The first insulating layer IL1 may include an inorganic insulating material such as silicon nitride (SiNₓ), silicon oxide (SiOₓ), and silicon oxynitride (SiOₓN_{y}). The first insulating layer IL1 may have a single-layer or multi-layer structure including the above inorganic insulating material.

A source electrode SE and a drain electrode DE may be disposed on the first insulating layer IL1. The source electrode SE and the drain electrode DE may be electrically connected to the source region S and the drain region D of the semiconductor layer ACT, respectively, by openings formed in the first insulating layer IL1, the second gate insulating layer GI2, and the first gate insulating layer GI1. Accordingly, the semiconductor layer ACT, the gate electrode GE1, the source electrode SE, and the drain electrode DE may constitute one transistor TFT. According to an embodiment, the transistor TFT may include only a source region and a drain region of the semiconductor layer ACT instead of the source electrode SE and the drain electrode DE.

The source electrode SE and the drain electrode DE may include a metal such as aluminum (Al), copper (Cu), silver (Ag), gold (Au), platinum (Pt), palladium (Pd), nickel (Ni), molybdenum (Mo), tungsten (W), titanium (Ti), chromium (Cr), tantalum (Ta), or the like, or a metal alloy thereof. The source electrode SE and the drain electrode DE may be formed as a single layer or multiple layers. The source electrode SE and the drain electrode DE according to an embodiment may be in a triple-layer configuration including an upper layer, an intermediate layer, and a lower layer, wherein the upper layer and the lower layer may include titanium (Ti), and the intermediate layer may include aluminum (Al).

A second insulating layer IL2 is disposed on the source electrode SE and the drain electrode DE. The second insulating layer IL2 may cover the source electrode SE and the drain electrode DE. The second insulating layer IL2 may planarize the surface of the substrate SUB that has a transistor. The second insulating layer IL2 may be an organic insulating layer, and may include one or more materials of polyimide, polyamide, acrylic resin, benzocyclobutene, and phenol resin.

A first electrode E1 may be disposed on the second insulating layer IL2. The first electrode E1 is also referred to as an anode, and may be formed as a single layer including a transparent conductive oxide layer or a metallic material or as multiple layers including them. The transparent conductive oxide layer may include indium tin oxide (ITO), poly-ITO, indium zinc oxide (IZO), indium gallium zinc oxide (IGZO), indium tin zinc oxide (ITZO), and the like. The metallic material may include silver (Ag), molybdenum (Mo), copper (Cu), gold (Au), and aluminum (Al). For example, the first electrode E1 may have a triple-layer structure of ITO/Ag/ITO.

The first electrode E1 may be physically and electrically connected to the drain electrode DE through an opening of the second insulating layer IL2. Accordingly, the first electrode E1 may receive an output current to be transferred from the drain electrode DE to a light emitting layer EML.

A pixel defining layer PDL may be disposed on the first electrode E1 and the second insulating layer IL2. The pixel defining layer PDL may overlap an edge of the first electrode E1, and may be separated from a central portion of the first electrode E1. The pixel defining layer PDL may define the position of the light emitting layer EML such that the light emitting layer EML may be disposed on an exposed surface of the first electrode E1. The pixel defining layer PDL may be an organic insulating layer including at least one material selected from a group including polyimide, polyamide, acrylic resin, benzocyclobutene, and phenol resin, and according to another embodiment, the pixel defining layer PDL may be formed as a black pixel defining layer BPDL including a black pigment.

The light emitting layer EML may be disposed in the openings of the pixel defining layer PDL. The light emitting layer EML may include an organic material that emits light such as red, green, and blue light. The light emitting layer 350 emitting red, green, and blue light may include a low-molecular or high-molecular organic material. In FIG. 3, the light emitting layer EML is depicted as a single layer, but in reality, auxiliary layers such as an electron injection layer, an electron transport layer, a hole transport layer, and a hole injection layer may also be included above and below the light emitting layer EML, the hole injection layer and the hole transport layer may be disposed below the light emitting layer EML, and the electron transport layer and the electron injection layer may be positioned above the light emitting layer EML.

The second electrode E2 may be disposed on the pixel defining layer PDL and the emission layer EML. The second electrode E2 may be referred to as a cathode, and may be formed of a transparent conductive layer including indium tin oxide (ITO), indium zinc oxide (IZO), indium gallium zinc oxide (IGZO), indium tin zinc oxide (ITZO), etc. In addition, the second electrode E2 may have a translucent characteristic, and in this case, it may constitute a micro-cavity together with the first electrode E1. According to such a micro-cavity structure, light of a specific wavelength is emitted to an upper part by the characteristics and spacing between both of the electrodes, and as a result, red, green, or blue light may be displayed.

The first electrode E1, the light emitting layer EML, and the second electrode E2 may constitute a light emitting element ED.

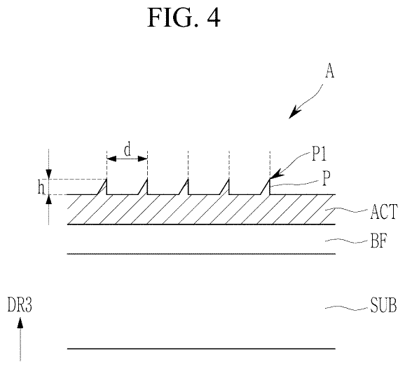

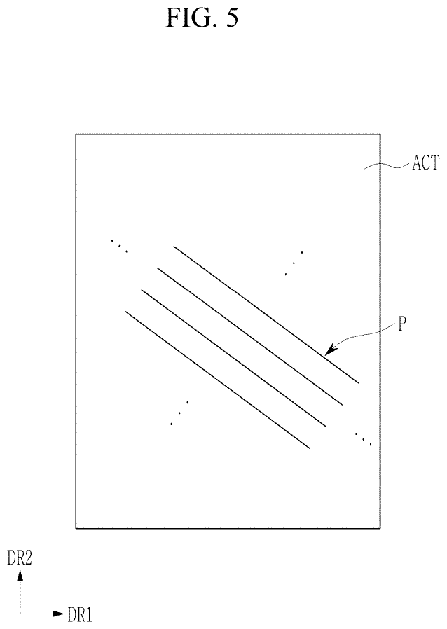

Hereinafter, a shape of the semiconductor layer ACT will be described in detail with reference to FIGS. 4 and 5. FIG. 4 is an enlarged cross-sectional view of a region A of FIG. 3. FIG. 5 is a top plan view schematically showing a plurality of protrusions in the semiconductor layer ACT.

Referring to FIG. 4, the semiconductor layer ACT may include the plurality of protrusions P on a surface. The plurality of protrusions P may be disposed at an interval in a cross-sectional view. The plurality of protrusions P may protrude from the surface of the semiconductor layer ACT in the third direction DR3, and may have a pointed tip P1 that is farthest from the flat portion of the semiconductor layer ACT. The plurality of protrusions P may have a triangular shape in a cross-sectional view, with one of the two sides extending from the tip P1 being longer than the other side, and the two sides having different slopes with respect to the surface of the semiconductor layer ACT. As depicted in FIG. 5, each one of the protrusions P extends in a substantially straight line.

The plurality of protrusions P may be separated by a distance d. The distance d between the plurality of protrusions P may be 1.5 μm or less, 0.9 μm or less, or 0.878 μm or less.

The plurality of protrusions P may have a constant height h corresponding to the distance from the flat surface of the semiconductor layer ACT to the tip P1 in the third direction DR3. The height h of the plurality of protrusions P may be 6 nm or less, or 4 nm or less.

This specification illustrates an enlarged view of a portion of the channel region C, but it is not limited thereto, and the source region S and the drain region D of the semiconductor layer ACT may also have a cross-section similar to that in FIG. 4.

Referring to FIG. 5, each one of the protrusions P may extend in a line that is oblique with respect to at least one of the first direction DR1 and the second direction DR2 in a plan view. That is, each of the plurality of protrusions P may extend obliquely from an edge of the substrate SUB. The plurality of protrusions P may form an angle of 30° to 60° with respect to the first direction DR1 and the second direction DR2 in a plan view. The plurality of protrusions P may extend in a direction perpendicular to a silicon crystal direction <100> in the semiconductor layer ACT.

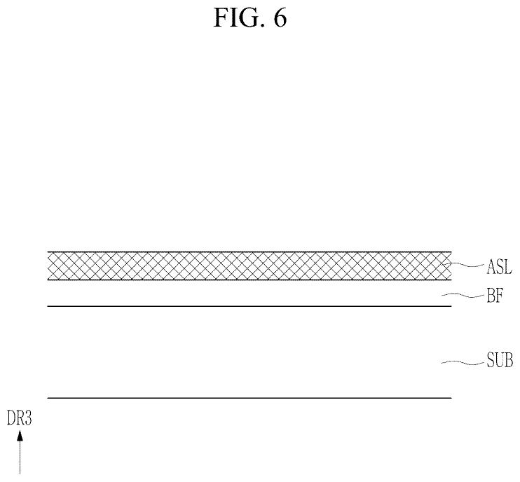

Hereinafter, a manufacturing method for a display device according to an embodiment will be described with reference to FIG. 6 to FIG. 16. FIG. 6 to FIG. 16 illustrate a manufacturing method for a display device according to an embodiment. A description of components that are the same as the components described above will be omitted.

By referring to FIG. 6, an amorphous silicon layer ASL may be formed on the substrate SUB and the buffer layer BF. The amorphous silicon layer ASL may include amorphous silicon. The amorphous silicon layer ASL may be stacked in a rectangular shape on the buffer layer BF, and may extend in the first direction DR1 and the second direction DR2.

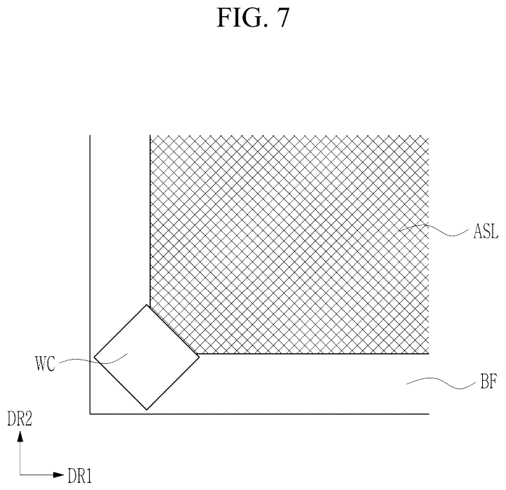

Then, referring to FIG. 7, a single-crystal silicon chip WC may be attached to a corner of the amorphous silicon layer ASL. The single-crystal silicon chip WC may be a wafer made of single-crystal silicon. The single-crystal silicon chip WC may be attached to the amorphous silicon layer ASL so that the <100> silicon crystal direction is oblique to the first direction DR1 and the second direction DR2, and may form an angle of 30° to 60°. For example, in the single-crystal silicon chip WC, the <100> silicon crystal direction may be parallel to the diagonal direction from the corner to another corner of the amorphous silicon layer ASL.

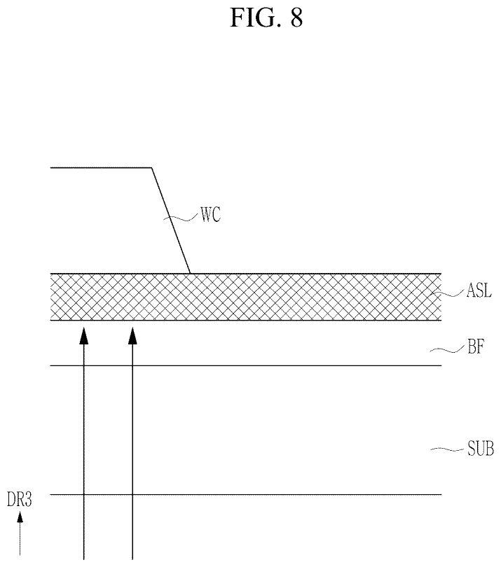

Specifically, referring to FIG. 8, the single-crystal silicon chip WC may be bonded on the amorphous silicon layer ASL. In this case, a lower portion of the substrate SUB may be irradiated with a laser beam to bond the amorphous silicon layer ASL and the single-crystal silicon chip WC. An area where the amorphous silicon layer ASL and the single-crystal silicon chip WC come into contact may be locally melted, allowing the single-crystal silicon chip WC to be attached to the corner of the amorphous silicon layer ASL.

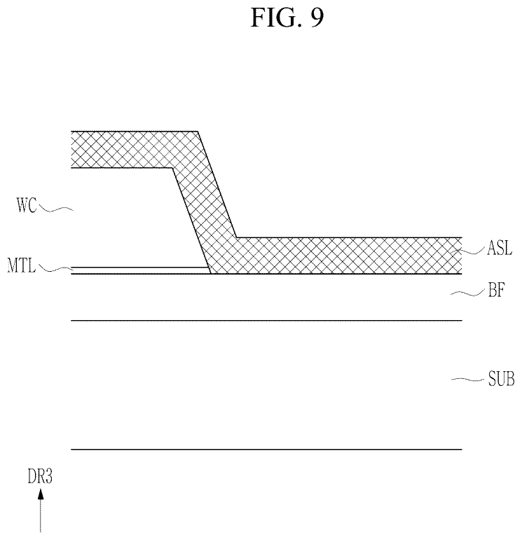

The present disclosure is not limited thereto, and referring to FIG. 9, the single-crystal silicon chip WC may be bonded to a lower surface of the corner of the amorphous silicon layer ASL. A metal film MTL, such as gold (Au) or aluminum (Al) film, may be attached to the buffer layer BF. The single-crystal silicon chip WC may be disposed on the metal film MTL, and the contact area may be locally melted to form eutectic bonding of the buffer layer BF, the metal film MTL, and the single-crystal silicon chip WC.

Then, a surface of the single-crystal silicon chip WC may be cleaned. The surface of the single-crystal silicon chip WC may be cleaned using an HF cleaning solution to remove an oxide layer on the surface.

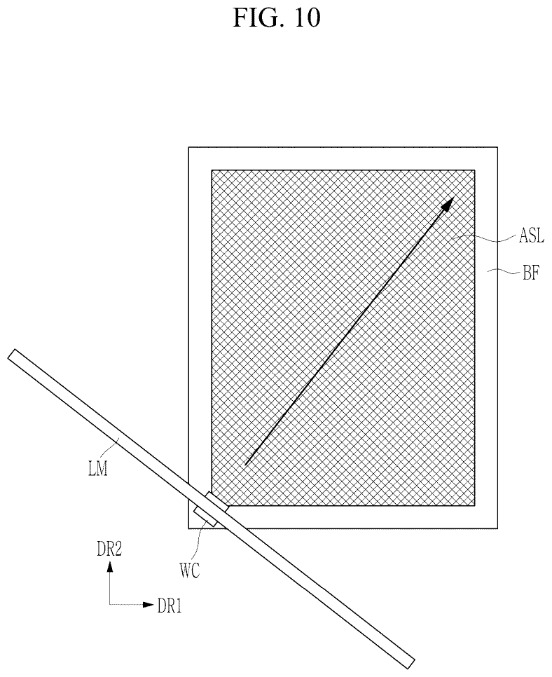

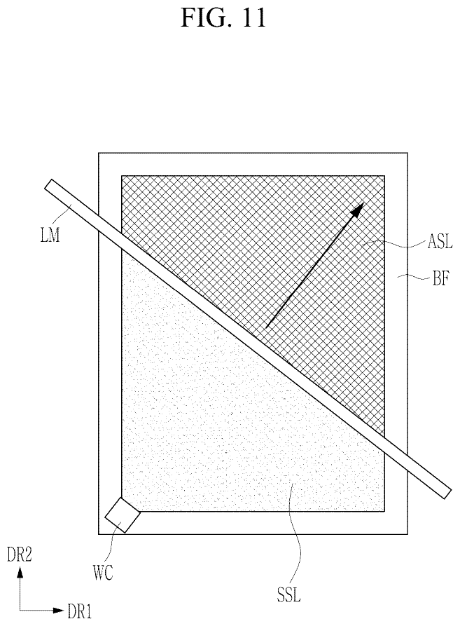

Referring to FIGS. 10 and 11, a single-crystal silicon layer SSL may be formed by moving a laser beam from the corner of an amorphous silicon layer ASL to the diagonally opposite corner, in the direction of the arrow that is shown. In this case, a laser module LM may intermittently generate a laser beam to irradiate the amorphous silicon layer ASL. For example, the laser module LM may generate a thin laser beam of several micrometers, and may generate a short-wavelength, high-power, and high-efficiency laser beam. Pulse duration is not limited as long as sufficient crystal growth occurs. The pulse duration may be made sufficiently long by using a pulse extender PEX.

The moving direction of the laser beam may be oblique with respect to the first direction DR1 and the second direction DR2. An angle formed by the moving direction of the laser beam and the first direction DR1 or the second direction DR2 may be 30° to 60° in a plan view. The moving direction of the laser beam may be parallel to the <100> silicon crystal direction in a plan view. By moving the laser beam in the <100> silicon crystal direction, where crystal growth rate is the fastest, the growth rate of the single crystal may be maximized, thereby minimizing occurrence of defects.

Referring to FIG. 11, exposure to a laser beam from the laser module LM converts the amorphous silicon layer ASL to the single-crystal silicon layer SSL.

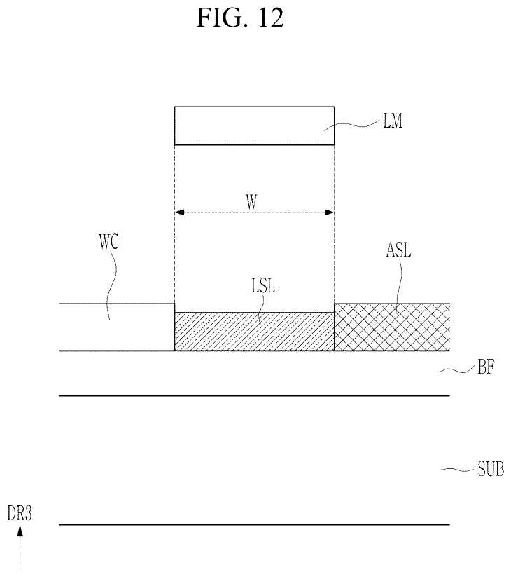

Specifically, referring to FIG. 12, first, the laser module LM may irradiate the corner of the amorphous silicon layer ASL to which the single-crystal silicon chip WC is attached. A beam width W, measured in the moving direction of the laser beam, may be less than 3 μm. The solid-state amorphous silicon layer ASL with the single-crystal silicon chip WC attached may absorb heat to melt into a liquid silicon LSL.

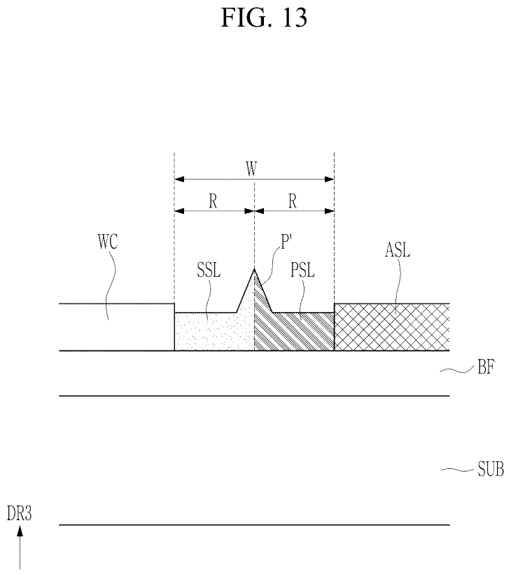

Then, referring to FIG. 13, after the laser beam passes, the liquid silicon LSL may release heat to change back to a solid state. During this heat release, the single-crystal silicon may grow laterally to form the single-crystal silicon layer SSL from the single-crystal silicon chip WC. Polycrystalline silicon may grow laterally to form a polycrystalline silicon layer PSL from the amorphous silicon layer ASL. A lateral-growth width R may be half of the beam width W. As a result, the single-crystal silicon layer SSL may be formed at one side, and the polycrystalline silicon layer PSL may be formed at the other side. A protrusion P′ may be formed in an intermediate region where the single-crystal silicon layer SSL and the polycrystalline silicon layer PSL meet. The beam width W is selected such that the liquid silicon LSL is not supercooled below its freezing point before the two-sided lateral crystal growth meets.

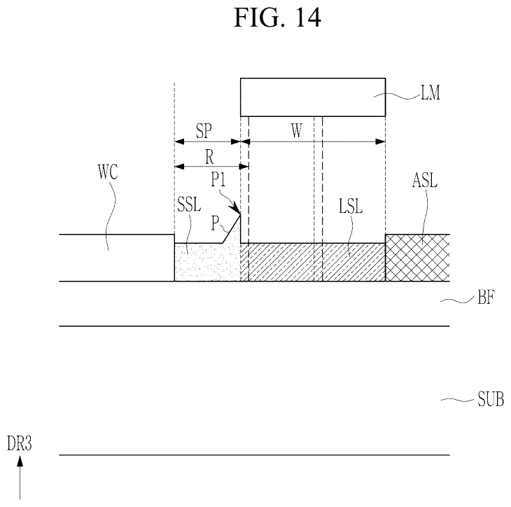

Then, referring to FIG. 14, the laser module LM or the substrate SUB may move by a scan pitch SP. The scan pitch SP, the distance traveled by the laser module LM between irradiation, may be less than or equal to half the beam width W of the laser beam. That is, the scan pitch SP may be less than or equal to the lateral-growth width R. For example, the scan pitch SP may be 1.5 μm or less, 0.9 μm or less, or 0.878 μm or less. Similarly, a region irradiated with the laser beam may be converted into the liquid silicon LSL. In this case, some regions including an apex of the protrusion P′ of FIG. 13 may melt to form the protrusion P with a lower height. That is, a tip P1 of the protrusion P has a smaller height than the apex of the protrusion P′ of FIG. 13.

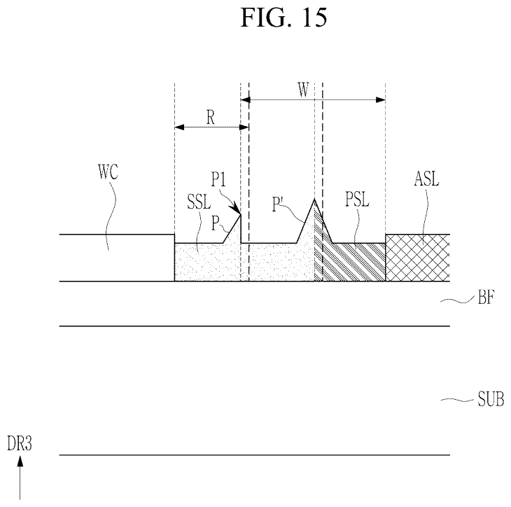

Then, referring to FIG. 15, the liquid silicon LSL may change back to a solid state. The single-crystal silicon layer SSL may grow from the single-crystal silicon layer SSL, and the polycrystalline silicon layer PSL may grow from the amorphous silicon layer ASL. The protrusion P′ may be formed in a middle area of the region irradiated with the laser beam.

By repeating the process described in FIGS. 14 and 15 to move the laser beam from one corner to another corner, e.g., the diagonally opposite corner, of the polycrystalline silicon layer PSL, the polycrystalline silicon layer PSL may grow into the single-crystal silicon layer SSL. The single-crystal silicon layer SSL may include single-crystal silicon. Furthermore, the single-crystal silicon layer SSL may include polycrystalline silicon having a crystal size of several micrometers or more.

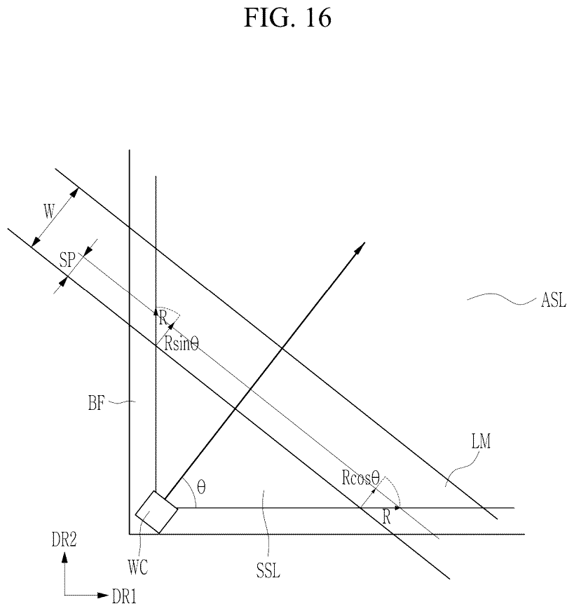

The scan pitch SP of the laser beam will be described in detail again with reference to FIG. 16. When an angle formed between the moving direction of the laser beam and the first direction DR1 is θ, the scan pitch SP may be smaller than R cos θ and R sin θ. A width of the single-crystal silicon layer SSL formed at a first edge of the amorphous silicon layer ASL may be R cos θ. At a second edge, the width of the formed single-crystal silicon layer SSL may be R sin θ. Accordingly, the scan pitch SP may be smaller than R cos θ and R sin θ, so an entire surface of the amorphous silicon layer ASL may be grown as the single-crystal silicon layer SSL.

Then, the single-crystal silicon layer SSL may be etched to form a single-crystal silicon pattern, and a gate electrode GE1 of FIG. 3 may be formed on the single-crystal silicon pattern. By partially implanting ions into a single-crystal silicon pattern, the semiconductor layer ACT of FIGS. 3 and 4 may be formed, and the source electrode SE and the drain electrode DE electrically connected to the semiconductor layer ACT may be formed. Referring to FIG. 3, the semiconductor layer ACT, the gate electrode GE1, the source electrode SE, and the drain electrode DE may constitute one transistor TFT. Then, the light emitting element ED of FIG. 3 electrically connected to at least one of the source electrode SE or the drain electrode DE may be formed.

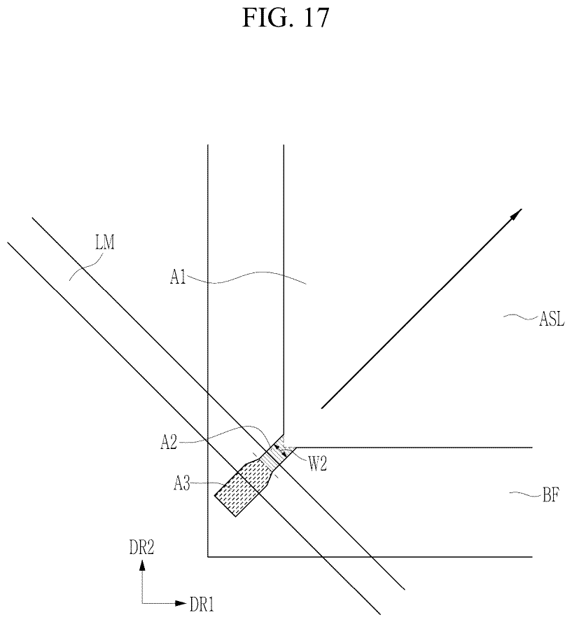

A manufacturing method for a display device according to another embodiment will now be described with reference to FIG. 17. A description of operations that is provided above as the manufacturing method for a display device will be omitted in the interest of avoiding redundancy.

First, referring to FIG. 6, an amorphous silicon layer ASL may be formed on the substrate SUB and the buffer layer BF.

Then, referring to FIG. 17, the amorphous silicon layer ASL may be etched to form a first area A1, a second area A2 connected to a corner of the first area A1, and a third area A3 connected to the second area A2. The first area A1 may have a rectangular shape. The second area A2 may be connected to the corner of the first area A1, and the width W2 of the connected portion may be less than 0.3 μm.

A laser beam may move from the third area A3 to the second area A2 and to the first area A1. The moving direction of the laser beam may be oblique to the first direction DR1 and the second direction DR2, such as the direction indicated by an arrow in FIG. 17. An angle formed by the moving direction of the laser beam and the first direction DR1 or the second direction DR2 may be 30° to 60° in a plan view. The moving direction of the laser beam may be parallel to the <100> silicon crystal direction in a plan view.

When the laser module LM irradiates the third area A3, polycrystalline silicon may be grown.

The laser module LM may form a single-crystal silicon layer ASL by moving a laser beam from the second area A2 to a diagonally opposite corner of the first area A1. Specifically, when the laser module LM irradiates the second area A2, the second area A2 may have a width W2 of 0.3 μm or less, so single-crystal silicon may grow. When the laser module LM moves from a corner of the first area A1 to a diagonally opposite corner through the second area A2, single-crystal silicon may be grown in the first area A1 similarly to the manufacturing method for a display device according to an embodiment. Furthermore, it may include polycrystalline silicon having a crystal size of several micrometers or more.

A description of the scan pitch SP of the laser beam is the same as that of the manufacturing method for a display device according to an embodiment.

While this disclosure has been described in connection with what is presently considered to be practical embodiments, it is to be understood that the disclosure is not limited to the disclosed embodiments, but, on the contrary, is intended to cover various modifications and equivalent dispositions included within the spirit and scope of the appended claims.
E2: second electrode
ED: light emitting element
P: plurality of protrusions
ASL: amorphous silicon layer
WC: single-crystal silicon chip
SSL: single-crystal silicon layer
PSL: polycrystalline silicon layer

What is claimed is:

1. A display device comprising:
a substrate having edges that extend in a first direction and a second direction;
a transistor disposed on the substrate; and
a light emitting element electrically connected to the transistor,
wherein the transistor includes a semiconductor layer including single-crystal silicon,
the semiconductor layer includes a plurality of protrusions,
a distance between the plurality of protrusions is 1.5 μm or less, and
each of the plurality of protrusions extends in a line that is oblique to at least one of the first direction and the second direction in a plan view.

2. The display device of claim 1, wherein
the distance between the plurality of protrusions is 0.9 μm or less.

3. The display device of claim 2, wherein
the distance between the plurality of protrusions is 0.878 μm or less.

4. The display device of claim 1, wherein
the plurality of protrusions form an angle of 30° to 60° with respect to at least one of the first direction and the second direction.

5. The display device of claim 1, wherein
the plurality of protrusions extend in a direction perpendicular to a <100> silicon crystal direction in a plan view.

6. The display device of claim 1, wherein
a height of the plurality of protrusions in a cross-sectional view is 6 nm or less.

7. The display device of claim 6, wherein
the height of the plurality of protrusions in a cross-sectional view is 4 nm or less.

8. The display device of claim 1, wherein
the transistor further includes:
a source electrode and a drain electrode electrically connected to the semiconductor layer; and
a gate electrode overlapping a portion of the semiconductor layer, and
the light emitting element electrically connected to at least one of the source electrode or the drain electrode.

9. A manufacturing method for a display device, comprising:
preparing a substrate having edges that extend in a first direction and a second direction;
forming a transistor on a substrate; and
forming a light emitting element electrically connected to the transistor,
wherein the forming of the transistor includes:
forming an amorphous silicon layer;
attaching a single-crystal silicon chip to a corner of the amorphous silicon layer; and
forming a single-crystal silicon layer by moving a laser beam from the corner of the amorphous silicon layer to another corner,
wherein a moving direction of the laser beam is oblique to at least one of the first direction and the second direction in a plan view.

10. The manufacturing method of claim 9, wherein
a beam width of the laser beam is 3 μm or less.

11. The manufacturing method of claim 10, wherein
a scan pitch of the laser beam is less than or equal to ½ of the beam width.

12. The manufacturing method of claim 11, wherein
the scan pitch of the laser beam is 0.878 μm or less.

13. The manufacturing method of claim 9, wherein
the moving direction of the laser beam is 30° to 60° relative to one of the first direction and the second direction.

14. The manufacturing method of claim 9, wherein
the forming of the transistor includes:
forming a single-crystal silicon pattern by etching the single-crystal silicon layer;
forming a gate electrode on the single-crystal silicon pattern; and
forming a semiconductor layer by partially implanting ions into the single-crystal silicon pattern.

15. An electronic device comprising a display device, the display device comprising:
a substrate having edges that extend in a first direction and a second direction;
a transistor disposed on the substrate; and
a light emitting element electrically connected to the transistor,
wherein the transistor includes a semiconductor layer including single-crystal silicon,
the semiconductor layer includes a plurality of protrusions that extend in parallel lines oblique to at least one of the first direction and the second direction in a plan view, and
a distance between the plurality of protrusions is 1.5 μm or less.

16. The electronic device of claim 15, wherein
the distance between the plurality of protrusions is 0.9 μm or less.

17. The electronic device of claim 16, wherein
the distance between the plurality of protrusions is 0.878 μm or less.
